(19) United States
(12) Patent Application Publication
(10) Pub. No.: US 2005/0166172 A1
(43) Pub. Date: Jul. 28, 2005

(54) Critical pattern extracting method, critical pattern extracting program, and method of manufacturing semiconductor device

(76) Inventors: Daisuke Kawamura, Kanagawa (JP); Shigeki Nojima, Kanagawa (JP); Shoji Mimotogi, Kanagawa (JP)

Correspondence Address: FINNEGAN, HENDERSON, FARABOW, GARRETT & DUNNER;LLP, 901 NEW YORK AVENUE, NW, WASHINGTON, DC, 20001-4413, US

(21) Appl. No.: 11/006,532

(22) Filed: Dec. 8, 2004

(30) Foreign Application Priority Data
Dec. 8, 2003 (JP) 2003-409015

(51) Int. Cl. G03F 9/00; G06F 17/50

(52) U.S. Cl. 716/19; 430/5; 716/20; 716/21

(57) ABSTRACT

According to a aspect of the present invention, there is provided a critical pattern extracting method which extracts critical patterns from mask data for manufacturing a photomask used in a lithography step, comprising at least: extracting mask data of a peripheral region within a predetermined range from an interested portion to be decided in the mask data; defining portions constituting the peripheral region as reference portions and calculating process generation amounts generated from the each reference portion in the lithography step by simulation; performing a predetermined arithmetic operation by using the process generation amounts and distances between the interested portion and the each reference portion; performing multiple integral of an arithmetic operation value obtained by the predetermined arithmetic operation in the peripheral region or an arithmetic operation equivalent to the multiple integral to calculate a process affecter amount; and comparing the process affecter amount with a predetermined threshold value.

### CROSS REFERENCE TO RELATED APPLICATIONS

This application claims the benefit of priority under 35USC § 119 to Japanese Patent Application No. 2003-409015 filed on Dec. 8, 2003, the entire contents of which are incorporated herein by reference.

### BACKGROUND OF THE INVENTION

1. Field of the Invention

The present invention relates to a critical pattern extracting method and program which extracts a critical pattern from mask data of a photomask used in lithography process in manufacturing a semiconductor device, a magnetic device, or the like, and a method of manufacturing a device.

2. Related Art

As a film thickness of a resist film used in lithography, an aspect ratio of 3 or less is generally used to secure an process margin against deterioration of resolution and pattern collapse caused by shrinkage of feature size of a circuit pattern. For example, in the case where the minimum line width in lithography is 90 nm, the resist film having a film thickness of about 300 nm is used. The resist film is an etching mask used for processing a film under the resist film, i.e., the films finally left as a part of a semiconductor device. The reduction of resist film causes elimination of a process margin in the etching processing of the film under the resist film. A few shortage of thickness of a resist film, which does not cause any problem in manufacturing processes for semiconductor devices having a large feature size, causes a problem in processing of an underlying film having a small feature size.

In a conventional technique, mask data is subjected to correction called OPC (Optical Proximity Correction) or PPC (Process Proximity Correction) (to be uniformed as PPC hereinafter), so that the shapes of a resist film pattern after the lithography or a processed underlying film pattern is changed into a desired shape. In general PPC, high-speed processing is considered as an important factor for processing enormous quantity of mask data, and the accuracy of the correction is sacrificed to some extent. For this reason, simulation is performed by using mask data corrected by PPC under the same conditions as those in the PPC and conditions different from those in the PPC to decide whether correction is sufficiently performed to mask data (critical pattern) suspected to be insufficiently corrected. If the correction is insufficient, the correction is usually performed for a subset of the critical pattern again.

However, with shrinkage of the feature size, even though theoretical intensity distributions of exposure light irradiated on a resist film is equal in other points, there is a phenomenon in which three-dimensional shapes (in particular, the shape of a resist head portion) of a resist film on a wafer are different each other. A measurement of a photomask can be measured by using an AIMS (Aerial Image Measurement System). A range of influence of optical proximity effect is several micromillimeters at most. In the case where a measurement of photomask is equal to design value in the range of the influence of the optical proximity effect, it is expected that optical intensity distribution is also equal to design value. However, in practice, there is a case in which shape of a resist film and a thickness of a resist film are different each other.

In the case where the thickness of the resist film is different form the design value, the dimensions of the underlaying layer on the wafer change. In a serious situation, there is a phenomenon in which edge roughness caused by a shortage of thickness of the resist film in processing increases. At least one of the variation in dimension and the increase in edge roughness causes deterioration of performance such as a decrease in operation speed of a semiconductor device or an increase in required power in, e.g., a gate structure. In addition, the edge roughness in an element isolation pattern causes an increase in leak current caused by defective burying of an insulating film.

With respect to this point, in e.g., Japanese Unexamined Patent Publication No. 2002-148779, correction having an interest in a pattern layout in mask data, more specifically, a technique that correct mask data depending on a peripheral pattern density is disclosed. However, a greater part of the technique is based on a superficial data processing technique. For this reason, correction accuracy of a mask pattern cannot be fundamentally improved.

The present inventors focused on a solution of a cause bring a difference between the thickness of a resist film and a design value in the conventional technique. As a result, the present inventors found out the following models. That is, as mainly in PEB (Post Exposure Bake), acids vapored from the surface of a resist film is attached to a periphery of a resist film by an air current in a PEB unit, the characteristics of the resist film is changed at the attached portion (E. Shiobara, et al., Proc. SPIE, 4345, pp. 628-637, Kawamura Daisuke, et al., Spring Meeting 2001, Japan Society of Applied Physics, 28a-ZD-5, Matsunaga Kentaro et al., Spring Meeting 2001, Japan Society of Applied Physics, 28a-ZD-6), and a developing solution in spreading dissolves a resist film in the early stages of a developing step to deteriorate the normality of the developing solution, thereby changing the dissolution characteristics of the resist film.

### BRIEF DESCRIPTION OF THE DRAWINGS

FIG. 1 is a block diagram showing the configuration of a critical pattern extracting system for realizing a critical pattern extracting procedure according to a first embodiment;

FIG. 2 is a block diagram showing a typical configuration of a system having a critical pattern extracting function;

FIG. 3 is a pattern diagram showing a manner in which the film thickness of a resist film is measured while changing a distance from an end of an Open exposure area;

FIG. 4 is a graph showing a state in which a maximum distance to a position where vapored acids is attached again is estimated on the basis of the measurement result shown in FIG. 3;

FIG. 5 is a graph showing a manner in which a decrease in film thickness is acquired in various distances from the center of the Open exposure area within a range extending from the end of the Open exposure area by the maximum distance;

FIG. 6 is a graph showing a relation between a distance from the center of the Open exposure area and a decrease in thickness of the resist film with respect to each amount of exposure;

FIG. 7 is a graph showing a relation between an amount of attached acids at an unexposed portion and the decrease in film thickness;

FIG. 8 is a graph for explaining a fifth stage of a critical pattern extracting procedure;

FIG. 9 is a graph showing a relation between an inter-central distance and the decrease in film thickness with respect to each amount of exposure;

FIG. 10 is a graph showing a relation among an amount of exposure to a film thickness measurement position (interested position), an amount of attached acids, and a decrease in film thickness;

FIG. 11 is a diagram showing the configuration of a critical pattern extracting system for realizing a critical pattern extracting procedure according to a fifth embodiment;

FIG. 12 is a graph showing a relation among an amount of dissolution of a resist film in a developing solution, an amount of irradiation onto an interested position, and a decrease in film thickness;

FIG. 13 is a diagram showing an example of mask data;

FIG. 14 is a graph showing a relation between an amount of vapored acids and an amount of generated acids; and

FIG. 15 is a block diagram showing the configuration of a critical pattern extracting system for realizing a critical pattern extracting procedure according to a sixth embodiment.

### SUMMARY OF THE INVENTION

According to a first aspect of the present invention, there is provided a critical pattern extracting method which extracts critical patterns from mask data for manufacturing a photomask used in a lithography step, comprising at least: extracting mask data of a peripheral region within a predetermined range from an interested portion to be decided in the mask data; defining portions constituting the peripheral region as reference portions and calculating process generation amounts generated from the each reference portion in the lithography step by simulation; performing a predetermined arithmetic operation by using the process generation amounts and distances between the interested portion and the each reference portion; performing multiple integral of an arithmetic operation value obtained by the predetermined arithmetic operation in the peripheral region or an arithmetic operation equivalent to the multiple integral to calculate a process affecter amount; and comparing the process affecter amount with a predetermined threshold value.

According to a second aspect of the present invention, there is provided A critical pattern extracting method which extracts a critical pattern from mask data for manufacturing a photomask used in a lithography step, comprising at least: extracting mask data of a peripheral region within a predetermined range from an interested portion to be decided in the mask data; defining portions constituting the peripheral region as reference portions and calculating process generation amounts generated from the each reference portion in the lithography step by simulation; performing a predetermined arithmetic operation by using the process generation amounts and distances between the interested portion and the each reference portion; performing multiple integral of an arithmetic operation value obtained by the predetermined arithmetic operation in the peripheral region or an arithmetic operation equivalent to the multiple integral to calculate a process affecter amount; performing a further predetermined arithmetic operation by using the mask data of the interested portion, the process affecter amount, and a simulation parameter changing depending on the process affecter amount; and comparing an arithmetic operation value calculated by the further predetermined arithmetic operation with a predetermined threshold value.

According to a third aspect of the present invention, there is provided A critical pattern extracting program of making a computer execute a critical pattern extracting method which extracts a critical pattern from mask data for manufacturing a photomask used in a lithography step, comprising at least: extracting mask data of a peripheral region within a predetermined range from an interested portion to be decided in the mask data; defining portions constituting the peripheral region as reference portions and calculating process generation amounts generated from the each reference portion in the lithography step by simulation; performing a predetermined arithmetic operation by using the process generation amounts and distances between the interested portion and the each reference portion; performing multiple integral of an arithmetic operation value obtained by the predetermined arithmetic operation in the peripheral region or an arithmetic operation equivalent to the multiple integral to calculate a process affecter amount; and comparing the process affecter amount with a predetermined threshold value.

According to a fourth aspect of the present invention, there is a provided A critical pattern extracting program of making a computer execute a critical pattern extracting method which extracts a critical pattern from mask data for manufacturing a photomask used in a lithography step, comprising at least: extracting mask data of a peripheral region within a predetermined range from an interested portion to be decided in the mask data; defining portions constituting the peripheral region as reference portions and calculating process generation amounts generated from the each reference portion in the lithography step by simulation; performing a predetermined arithmetic operation by using the process generation amounts and distances between the interested portion and the each reference portion; performing multiple integral of an arithmetic operation value obtained by the predetermined arithmetic operation in the peripheral region or an arithmetic operation equivalent to the multiple integral to calculate a process affecter amount; performing a further predetermined arithmetic operation by using the mask data of the interested portion, the process affecter amount, and a simulation parameter changing depending on the process affecter amount; and comparing an arithmetic operation value calculated by the further predetermined arithmetic operation with a predetermined threshold value.

According to a fifth aspect of the present invention, there is a provided a method of manufacturing a semiconductor device, comprising: extracting mask data of a peripheral region within a predetermined range from an interested portion to be decided in mask data for manufacturing a photomask used in a lithography step; defining portions constituting the peripheral region as reference portions and calculating process generation amounts generated from the each reference portion in the lithography step by simulation; performing a predetermined arithmetic operation by using the process generation amounts and distances between the interested portion and the each reference portion; performing multiple integral of an arithmetic operation value obtained by the predetermined arithmetic operation in the peripheral region or an arithmetic operation equivalent to the multiple integral to calculate a process affecter amount; comparing the process affecter amount with a predetermined threshold value; extracting a critical pattern from the mask data for manufacturing the photo mask based on a result of the comparing; and preparing a photomask manufactured on the base of mask data which is corrected by using a information of a extracted critical pattern and exposuring a resist film on a wafer by using the photomask.

According to a sixth aspect of the present invention, there is a provided a method of manufacturing a semiconductor device, comprising: extracting mask data of a peripheral region within a predetermined range from an interested portion to be decided in the mask data; defining portions constituting the peripheral region as reference portions and calculating process generation amounts generated from the each reference portion in the lithography step by simulation; performing a predetermined arithmetic operation by using the process generation amounts and distances between the interested portion and the each reference portion; performing multiple integral of an arithmetic operation value obtained by the predetermined arithmetic operation in the peripheral region or an arithmetic operation equivalent to the multiple integral to calculate a process affecter amount; performing a further predetermined arithmetic operation by using the mask data of the interested portion, the process affecter amount, and a simulation parameter changing depending on the process affecter amount; comparing an arithmetic operation value calculated by the further predetermined arithmetic operation with a predetermined threshold value; extracting a critical pattern from the mask data for manufacturing the photo mask based on a result of the comparing; and preparing a photomask manufactured on the base of mask data which is corrected by using a information of a extracted critical pattern and exposuring a resist film on a wafer by using the photomask.

### DETAILED DESCRIPTION OF THE INVENTION

Embodiments to be described later based on the above models are intended to extract a critical pattern which may not be able to form a desired resist pattern from mask data at high accuracy.

The embodiments of the present invention will be described below with reference to the accompanying drawings.

### First Embodiment

As a characteristic feature of the embodiment, an amount of acids vapored from a periphery of an interested resist film during PEB (Post Exposure Bake) is used to calculate a concentration of acids in a vapor immediately above the interested resist film or a representative value of the concentration by simulation. Simulation is performed by using the calculated acid concentration to calculate a decrease in thickness of the interested resist film after development, and the calculated decrease in film thickness is compared with a threshold value. In this manner, it is decided whether a mask data portion corresponding to the interested resist film corresponds to a critical pattern or not.

In this case, the critical pattern is a pattern in mask data which constitutes barriers to realization of a desired function of a semiconductor device. More specifically, the critical pattern is a pattern in mask data which may induce a circuit malfunction. In this point, the critical patterns include not only a pattern in which at least one of dimensions of a resist pattern in wafer in-plane directions (planar directions) and edge roughness of the resist pattern do not meet standards but also a pattern in which the electric characteristics of a semiconductor device to which an underlying film processed by using a resist film as a sacrifice film is related. In short, the critical pattern means a pattern in which a three dimensional shape which includes a direction of thickness of the resist film serving as the sacrifice film does not meet the standards.

In a predetermined step in the lithography steps, as a part of a variation in state of a resist film, a material may be generated from the resist film. This material may adversely affect the state of the resist film around a position where the material is generated in a step (step A) in which the material is generated or/and a step (step B) subsequent to step A. An amount of the material (amount of substance) or an amount strongly correlated to the amount of substance is defined as “process generation amount”.

As an example of the precess generation amount, there is acids vapored from the surface of a resist film in the PEB step. The vapored acids is partially attached to the resist film at a position different from the generating position by an air current in the PEB unit again. This affects a deprotective reaction in the PEP step at the attached position, changes the surface state of the resist film, and also affects the developing step. In a positive chemical-amplification-type resist, the thickness of the resist pattern decreases in a resist pattern at a position where acids is attached to have a round-tipped shape, since deprotective reaction in resist resin at the portion where acids is attached progresses greatly. In a negative chemical-amplification-type resist, the upper portion of the resist pattern has a T-top shape.

The vaporization of acids affects the shape of the resist film at an interested point located around the vaporization portion. An amount of substance serving as an amount which directly affects the resist film at the interested point is an mount of acids in an intermediate layer above the interested point, the amount of acids in the intermediate layer regulating an mount of acids attached to the interested point. With respect to an amount of acids attached to the interested point, it is considered that an acids generated and vapored in a peripheral environment of the interested point reaches the interested point with a predetermined probability depending on a distance of the generation portion and the interested point. More specifically, the amount of attached acids in the amount of acids generated and vapored from the periphery of the interested point can be considered as an amount practically acting on the resist film at the interested point.

In this manner, in the process generation amount, an amount which actually affects the resist film at the interested point or an amount strongly correlated to the amount is defined as “process affecter amount”.

A distance for which acids vapored from the periphery of the interested point affects the shape of the resist film at the interested point ranges from 100 um to several mm. On the other hand, the distance within which the optical proximity acts ranges from about 1.5 to 2 um in KrF lithography. As described above, in the embodiment, the peripheral environment of the interested point considered in calculation of the process affecter amount includes a region extending from the interested point, the region including a region overreaching the distance within which the optical proximity acts for the interested point.

Extraction (resist process simulation) of a critical pattern in the case where the process generation amount is defined as an amount of vapored acids in the peripheral environment in at least one of exposure and PEB will be described below. In the resist process simulation, as will be described later, at least a generation rate of acids from a photo-acid generator in the resist film and a diffusional reaction and a chemical reaction in PEB are considered to extract a critical pattern.

A method of calculating an acid concentration above an interested resist film by using an amount of acids vapored from a resist film around an interested point will be described below. Thereafter, the resist process simulation will be described in detail.

Reactions in steps (exposure, PEB, and development) of a process using a chemical-amplification-type resist are expressed by the following equations (Equation 1) to (Equation 6) in consideration of an acid, a base, and protection rates of a base resin by a dissolution-inhibition group, in the resist film. In addition, there is a model to which a reaction order or a high-order reaction is added. Also in this case, the same concept as in the embodiment can be applied. In order to simplify a numerical expression, an amount of acids and an amount of base are generally described by a standardized amount of acids and a standardized amount of base which are standardized by a PAG (Photo Acid Generator), and a protection rate is described by a standardized protection rate standardized by a protection rate in an unexposed state.

(1) Exposure
[A](t=0)=(1−exp(−C×Eᵢ×I(x,y,z)))) (Equation 1)
[A]: Standardized acid concentration, C: PhotoSpeed in parameter of Dill,
Ei: Set amount of exposure, I: Electric field intensity

(2) PEB

$$\begin{matrix}\begin{matrix}\frac{\partial [ A ]}{\partial t} = ∇ ( {D}_{Acid} ∇ [ A ] ) - {k}_{neutral} [ A ] [ B ] - \\ {k}_{AcidLoss} [ A ] - {k}_{sub \text{-} react} [ A ] [ P ]\end{matrix} & ( Equation 2 ) \\ \frac{\partial [ B ]}{\partial t} = ∇ ( {D}_{Base} ∇ [ B ] ) - {k}_{neutral} [ A ] [ B ] - {k}_{BaseLoss} [ B ] & ( Equation 3 ) \\ \frac{\partial [ P ]}{\partial t} = - {k}_{deprotection} [ A ] [ P ] - {k}_{thermal} [ P ] \\ t = 0 \\ \begin{matrix}[ A ] = ( 1 - exp ( - C \times {E}_{i} \times I ( x , y , z ) ) ) ) \\ [ B ] = {B}_{0} \\ [ P ] = 1\end{matrix} & ( Equation 4 )\end{matrix}$$

B.C. (Boundary Condition)

$$Z = Tr \cdot {D}_{Acid} \frac{\partial [ A ]}{\partial z} = h ( [ A ] - {[ A ]}_{0} ) \qquad ( Equation 5 )$$
[B]: Standardized base concentration, [P] Standardized protection rate,
B₀: Standardized base concentration in unexposed state
[A]₀: Acid concentration of intermediate layer above resist surface
kₙₑᵤₜᵣₐₗ: Reaction coefficient of neutralization reaction between acid and base, D_{Acid}: Diffusion constant of acid,
k_{AcidLoss}: Reaction coefficient of acid elimination reaction, k_{sub-react}: Reaction coefficient of sub-reaction in which acid is consumed,
k_{BaseLoss}: reaction coefficient of base elimination reaction, D_{Base}: Diffusion constant of base
K_{deprotection}: Reaction coefficient of deprotection reaction of acid, kₜₕₑᵣₘₐₗ: reaction coefficient of thermal decomposition reaction of protective group, Tr: Upper surface position (height) of resist film

It is noted that in not only PEB but also exposure, acid vaporization may occur on the upper surface of a resist film in an exposure device by that the resist film is heated by light absorption. The vapored acids is diffused by an air current on a wafer stage of the exposure device, and may be attached to another position distant from a vaporization position. In this case, while vaporization and attachment of acids under t<0 is considered, initial conditions (Equation 2) to (Equation 4) (PEB start time (t=0)) may be changed.

(3) Development
Dissolution Rate=Rate ([P]) (Equation 6)

As shown in (Equation 6), a developing rate depends on a standardized protection rate [P] in a developing stage. This standardized protection rate [P] is calculated by solving (Equation 2) to (Equation 4) by using a standardized acid concentration [A] obtained by calculating (Equation 1) in an exposure step, an initial standardized base concentration [B₀], a standardized protection rate [P] (t=0)=1 (initial value), and boundary conditions (Equation 5) of the upper surface of the resist film.

Therefore, the thickness of the interested resist film calculated by using (Equation 6) after the developing depends on the acid concentration [A]₀, included in (Equation 5), of the intermediate layer above the resist film.

For example, even though the pattern of the resist film at the interested position is the same, in the case where the acid concentration [A]₀ of the intermediate layer on the interested resist film changes due to a change of a pattern at a peripheral position, the shape (dimensions obtained after the development, a resist film thickness, or the like) of the interested resist film after the developing also changes. On the contrary, the acid concentration [A]₀ of the intermediate layer on the interested resist film is appropriately calculated to make it possible to predict the shape of the resist film at the interested position at high accuracy.

As shown in (Equation 5), the acid concentration [A]₀ of the intermediate layer above the resist film, as will be described later, depends on an amount of acids (process generation amount) vapored from the periphery of the resist film at the interested position, in particular, an amount of acids vapored from the upstream side of the air current to affect the film thickness of the interested resist film.

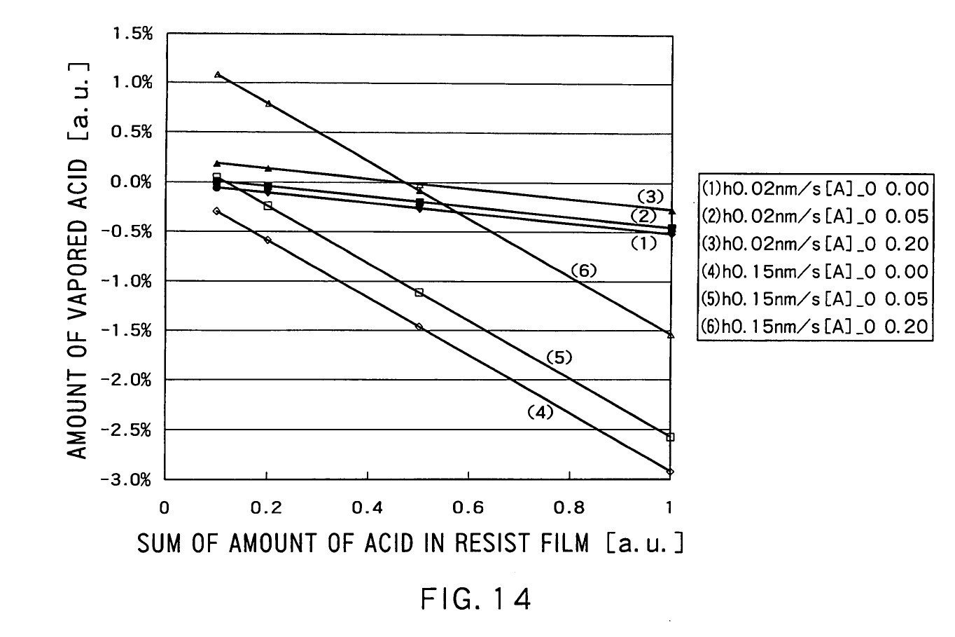

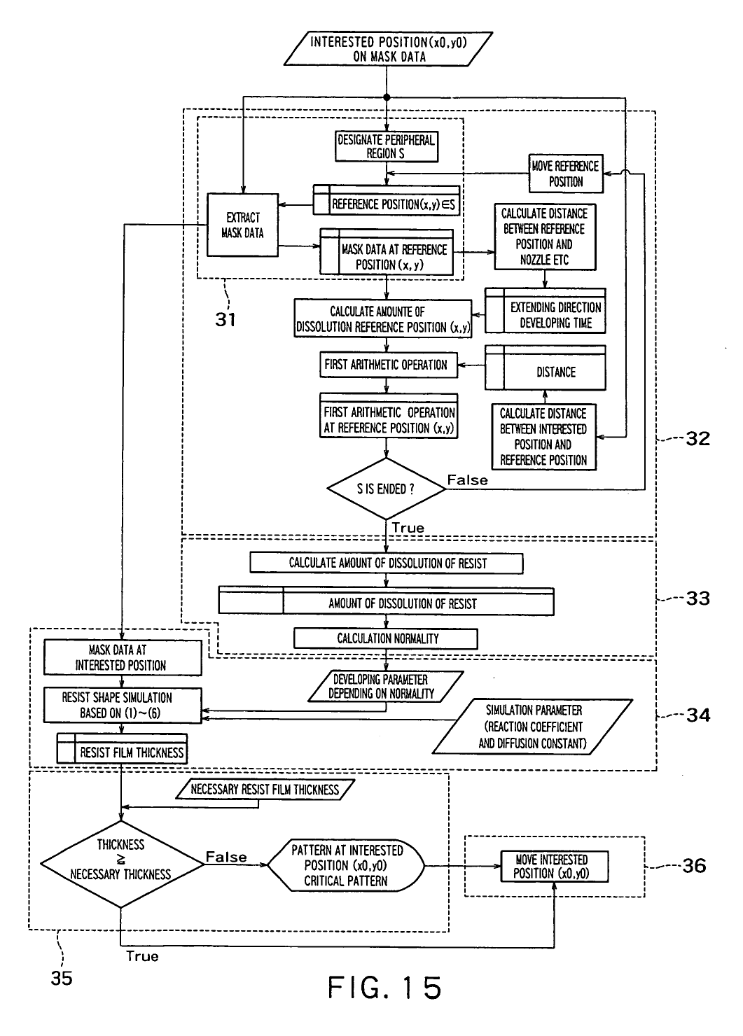

Here, a correlation between the acid concentration [A]₀ on the interested resist film (resist film at the interested position) and an amount of acids vapored from the resist film at a reference position (x,y) in a predetermined region (peripheral region) extending from the interested position will be described below. As is apparent from the boundary conditions (Equation 5), the amount of acids vapored from the reference position (x,y) is linearly related to the amount of acids generated from the reference position. In particular, in the case where [A]₀=0 is satisfied, an amount of vapored acids is in proportion to an amount of generated acids. FIG. 14 shows an example.

In consideration of the base amount B₀ added to the resist film, it is approximated that neutralization reaction between a acid and a base occurs immediately after acids is generated by exposure. At this time, if it is assumed that an amount of light absorption of the resist film in the direction of thickness is uniform, an amount AᵥₐₚΔxΔy of acids vapored from the resist film having a minute area ΔxΔy at the reference position (x,y) can be expressed by (Equation 7) by introducing a coefficient h′.

$${A}_{vap} ( x , y ) Δ x Δ y = \{ \begin{matrix}{h}^{′} [ exp \{ 1 - C \times {E}_{i} \times I ( x , y ) \} - {B}_{0} ] Tr Δ x Δ y & ( exp \{ 1 - C \times {E}_{i} \times I ( x , y ) \} \geq {B}_{0} ) \\ 0 & ( exp \{ 1 - C \times {E}_{i} \times I ( x , y ) \} < {B}_{0} )\end{matrix} \qquad ( Equation 7 )$$

Here, a distribution function obtained in the case where the acids vapored from the resist film at the reference position (x,y) moves to the resist film located at a position keeping a distance r away from the reference position is given by F(r). For example, if it is assumed that the vapored acids moves at random, the distribution function F(r) is assumed as a normal distribution. By using the distribution function F(r), an acid concentration [A]₀(x0,y0) of the intermediate layer on the resist film at the interested position (x0,y0) can be expressed as the following (Equation 9) as an arithmetic operation of an amount of vapored acids from the resist film at the reference position (x,y) and the distance r (see (Equation 8)) between the reference position (x,y) and the interested position (x0,y0).
r=\sqrt{(x−x0)²+(y−y0)²} (Equation 8)
[A]₀(x0,y0)=∫∫Aᵥₐₚ(x,y)·F(r)dxdy (Equation 9)

The distribution function F(r) in (Equation 9) and the coefficient h′ in the (Equation 7) can be determined by at least one of an experimental method and an analytical method.

Here, the mask data including a large number of openings and a very small number of large-scale remaining pattern means that a region of the resist film in which an amount of optically generated acids is smaller than an amount of base is very small. In this case, the lower line of (Equation 7) can be neglected. Therefore, (Equation 9) can be approximated to the form of (Equation 10) below.
[A]₀(x0,y0)≈h′∫∫[exp{1−C×Eᵢ×I(x,y))}−B₀]·F(r)dxdy (Equation 10)

The coefficient h′ and the distribution function F(r) in (Equation 10) are determined by at least one of an experiment method and an analytical method.

In the (Equation 9) and (Equation 10), an integral region of the distribution function F(r), i.e., a region in which an amount of vapored acids must be referred to is in a circle having a radius Lₘₐₓ and centered on the interested position (x0,y0). The radius Lₘₐₓ is a distance from the interested position (x0,y0) at which an acid distribution is almost 0, and is experimentally or analytically determined in advance. Here, in order to shorten a calculation time, the calculation may be performed by quadrature by parts obtained by dividing the integral region into finite cells without accurate multiple integral. In addition, although the calculation time and prediction accuracy are traded off, the distribution function F(r) may be approximated to 1 in the integral region or a set of parts of the integral region.

The acid concentration [A]₀ of the intermediate layer above the resist film at each interested position is calculated by using the (Equation 9) or (Equation 10). Simulation (to be described later) is performed by using the acid concentration [A]₀ in the intermediate layer to make it possible to appropriately estimate the shape of the resist film at each interested position.

A critical pattern extracting procedure (resist process simulation) according to the embodiment of the present invention will be described below. In the critical pattern extracting procedure, the thickness of the resist film at the interested position after developing is calculated by using predetermined resist process parameters (optical constant, PhotoSpeed, reaction coefficient in PEB, diffusion constant, and coefficient in developing description equation) of (Equation 1) to (Equation 6), the distribution function F(r) and the coefficient h′, the calculated acid concentration [A]₀ of the intermediate layer above the resist film at the interested position etc. The thickness of the resist film is compared with a predetermined threshold value to decide whether a mask data portion corresponding to the interested position corresponds to a critical pattern. The resist process simulation will be described below in detail.

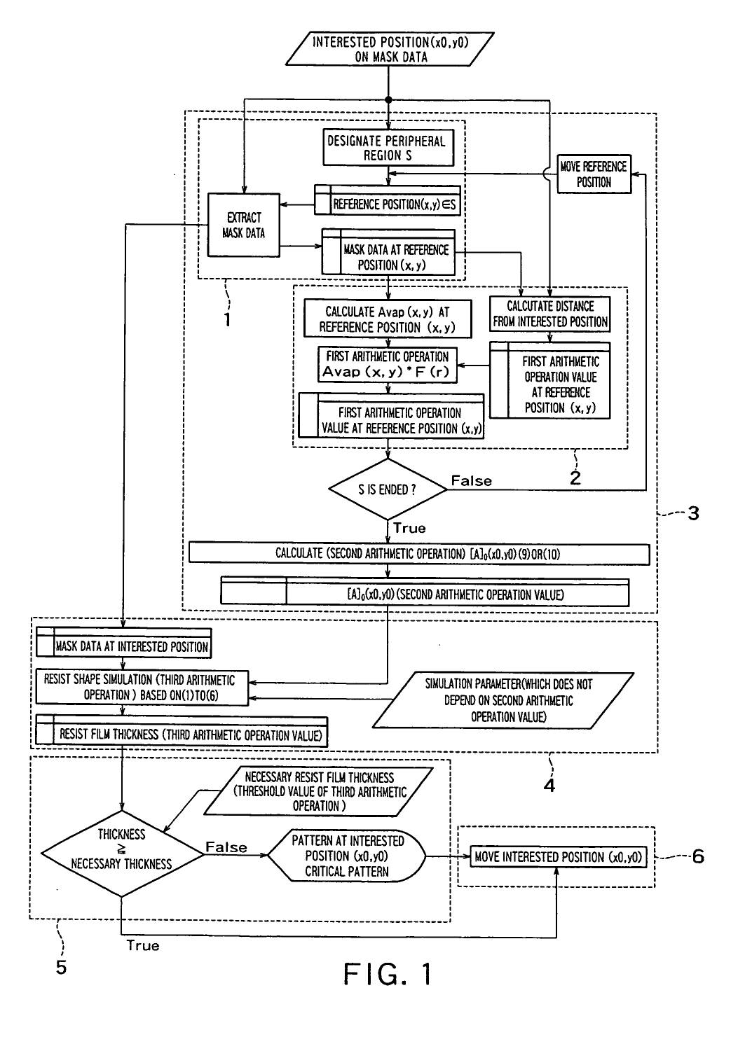

FIG. 1 is a block diagram showing the configuration of a critical pattern extracting system which realizes the critical pattern extracting procedure according to the embodiment.

The critical pattern extracting system includes six functional units (first functional unit 1 to sixth functional unit 6).

The first functional unit 1 extracts mask data at the interested position (x0,y0) from mask data obtained by a known method in advance. The first functional unit 1 calculate a region (peripheral region S) in a circle having a radius Lₘₐₓ and centered on the interested position (x0,y0) to specify the reference position (x,y) in the peripheral region S and extracts mask data at the reference position (x,y). Here, an operation for specifying the peripheral region S will be described below in more detail. It is noted that the planar shape of the peripheral region S is not limited to a circular shape. In view of required critical pattern extracting accuracy and the calculation time, the shape of the peripheral region S may be changed depending on a region in the mask data.

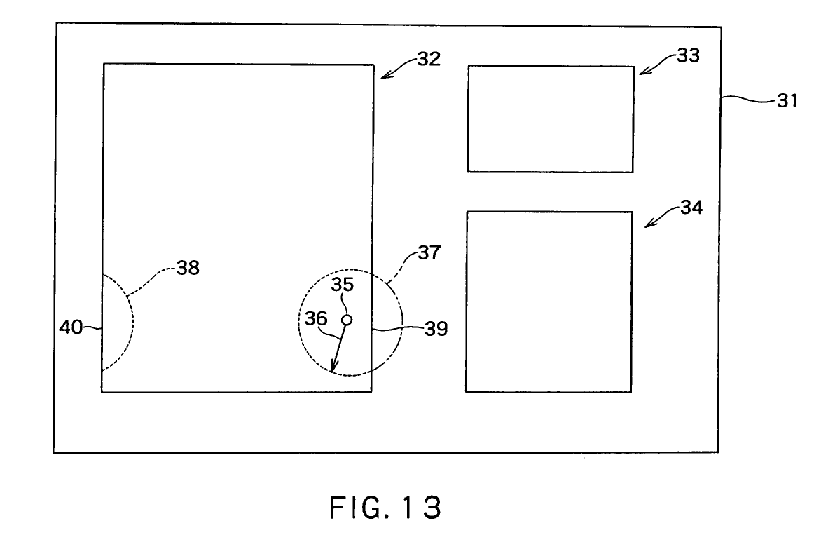

FIG. 13 is a diagram showing an example of mask data to be analyzed by the first functional unit 1.

Mask data 31 includes three patterns 32 to 34. The patterns 32 to 34 form resist patterns in different layers, respectively. More specifically, in exposure by the pattern 32, the other patterns 33 and 34 are not used.

For example, the pattern 32 is to be analyzed by the first functional unit 1. In the pattern 32, in the case where an interested position 35 is set, and in the case where the peripheral region is set in a circle having a radius 36, as indicated by a chain double-dashed line 37, this circle runs off the pattern 32.

In such a case, a boundary 39 of the pattern 32 off which the circle runs and a boundary 40 of the pattern 32 opposing the boundary 39 are considered as a continuous boundary. A region of a dotted line 38 shown in FIG. 13 corresponding to the chain double-dashed line 37 is defined as a part of the peripheral region.

Although the pattern 32 is described as the object to be analyzed, even though the pattern 33 or 34 is used as the object to be analyzed, the same is applied.

Returning to FIG. 1, the functional unit 2 calculate an amount of acids Aᵥₐₚ(x,y) vapored from the resist film corresponding to the reference position (x,y). In this case, the x- and y-coordinates may be converted from coordinates on the mask data into coordinates on a wafer. The functional unit 2 calculates a distance r between the interested position (x0,y0) and the reference position (x,y) on the resist film. The functional unit 2 performs a first arithmetic operation (Aᵥₐₚ(x,y×F(r)) (see (Equation 9) and (Equation 10)) by using the calculated amount of vapored acids Aᵥₐₚ(x,y) and the calculated distance r.

The functional unit 3 moves the reference position (x,y) and performs a first arithmetic operation with respect to all reference positions (x,y) in the peripheral region S. After the functional unit 3 performs the first arithmetic operation with respect to all the reference position (x,y) in the peripheral region S, the functional unit 3 applies (Equation 9) and (Equation 10) to calculate an acid concentration [A]₀(x0,y0) (second arithmetic operation value) of the intermediate layer above the resist film corresponding to the interested position (x0,y0) the interested position (x0,y0) (second arithmetic operation). An integral region of (Equation 9) or (Equation 10) is the peripheral region S.

The functional unit 4 applies the mask data at the interested position (x0,y0) calculated by the first functional unit 1, predetermined process parameters (parameters independent of the second arithmetic operation value) (for example, reaction coefficient, diffusion coefficient, developing parameter, and the like), and the acid concentration [A]₀(x0,y0) of the intermediate layer calculated by the functional unit 3 to (Equation 1) to (Equation 6) to calculate a shape (including a thickness Tr(x0,y0) of the resist film) of the resist film corresponding to the interested position (x0,y0).

More specifically, (Equation 1) in the exposure step is solved, and (Equation 2) to (Equation 5) in the PEB step are solved to calculate a standardized protection rate [P]. The functional unit 4 calculates a shape (including the thickness Tr(x0,y0) of the resist film) of the resist film after developing for a predetermined time on the basis of a relational expression between the standardized protection rate [P] and a developing rate shown at (Equation 6).

The functional unit 5 compares the thickness Tr(x0,y0) of the resist film corresponding to the interested position (x0,y0) with a predetermined threshold value (necessary resist film thickness) Tr_th. In the case where the thickness Tr(x0,y0) of the resist film is smaller than the predetermined threshold value Tr_th, the interested position (x0,y0) on the mask data is determined as a critical pattern. In this case, not only the thickness of the resist film, but also pattern dimensions of the resist film may be added to the criteria.

The sixth functional unit 6 moves the interested position (x0,y0) to perform the processes by the first functional unit 1 to the functional unit 5 again.

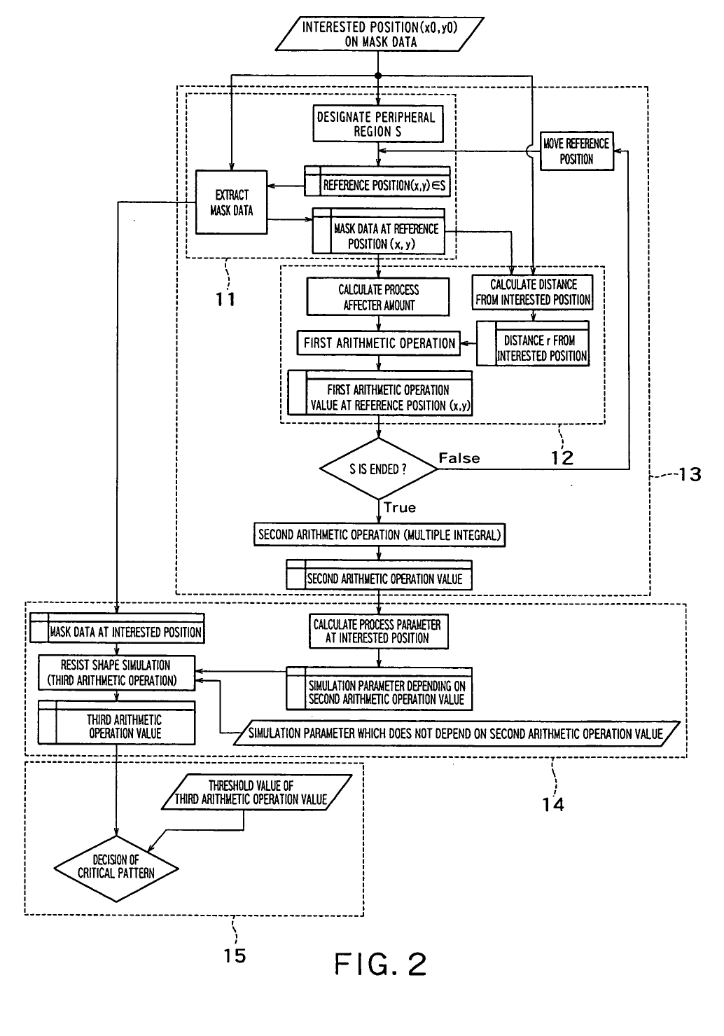

A system obtained by further generalizing the critical pattern extracting system is shown in FIG. 2. As an example of the generalization, in the system in FIG. 1, an amount of acids vapored from the resist film corresponding to the reference position on the mask data is used as the process generation amount. However, this limitation is not applied for the system in FIG. 2.

The configuration of the system in FIG. 2 is basically the same as the configuration of the system shown in FIG. 1. A first functional unit 11 to a fifth functional unit 15 in FIG. 2 correspond to the first functional unit 1 to the functional unit 5 shown in FIG. 1, respectively. However, a fourth functional unit 14 in FIG. 2 is slightly different from the functional unit 4 in FIG. 1.

More specifically, the functional unit 4 in FIG. 1 performs simulation by directionally using the acid concentration [A]₀ (x0,y0) (second arithmetic operation value) of the intermediate layer on the interested point calculated by the functional unit 3 as one of the parameters. On the other hand, the fourth functional unit 14 in FIG. 2 additionally performs calculating a value of a parameter changing depending on the second arithmetic operation value on the basis of the second arithmetic operation value calculated by the third functional unit 13. As a method of calculating the value of the parameter changing depending on the second arithmetic operation value, there is a method using a relational expression or a table formed in advance.

As described above, according to the embodiment, a reduction of the resist film after the development, is simulated by using the acid concentration of the intermediate layer on the interested resist film. For this reason, a critical pattern included in photomask data can be extracted while considering a direction of thickness of the resist film. This effect will be more concretely described below.

Conventionally, an increase in pattern density of a resist pattern or complication of a layout of a resist pattern caused by shrinkage of feature size makes an increase in critical patterns obvious.

However, conventional extraction of a critical pattern merely gives attention to a shape of a resist film in an in-plane direction of a wafer, i.e., dimensions of the resist film. More specifically, the conventional technique does not cope with extraction of a critical pattern in consideration of the direction of thickness of the resist film. For example, the conventional technique does not cope with a problem of a variation in thickness of the resist film depending on positions after developing. In addition, the conventional technique does not cope with the following problems at all. That is, in the case where the thickness of the resist film is short, even though the dimensions of the resist film in an in-plane direction fall within an allowable range, the dimensions of a film to be processed fall outside a allowable value. Furthermore, even though the dimensions of the film to be processed fall within the allowable range, a shape of a pattern side wall of the film to be processed falls outside an allowable range. For this reason, a critical pattern cannot be appropriately extracted. With the shrinkage of feature size, critical patterns increase in number. Consequently, a yield of semiconductor devices decreases.

In contrast to this, in the embodiment, a critical pattern can be accurately extracted also in consideration of the direction of thickness. For this reason, the yield can be increased. As a result, a reduction in cost is achieved by a reduction in probability of reformed photomask, and development time for semiconductor devices can be expected to be shortened.

According to the embodiment, since a boundary of valid mask data region (portions obtained by removing mask data portions which are not related to pattern formation from the mask data) is handled to be connected to a boundary opposing the boundary, a process affecter amount can be appropriately estimated with respect to an interested point near the boundary of the valid mask data region. Therefore, even near an edge of the valid mask data region, a critical pattern can be decided at high accuracy.

### Second Embodiment

In the first embodiment, in the case where the base amount B₀ is sufficiently small, a term of B₀ in (Equation 10) is separated to make it possible to change (Equation 10) into (Equation 11). In this equation, G denotes a constant.
[A]₀(x0, y0)≈h′∫∫exp{1−C×Eᵢ×I(x,y))}·F(r)dxdy−G (Equation 11)

In this (Equation 11), values h′, F(r), and G may be calculated by at least one of an experiment method and an analytic method.

(Equation 11) has a form which is simpler than that of (Equation 9). Therefore, a calculation time in the second embodiment can be made shorter than that in the first embodiment.

### Third Embodiment

In the first embodiment, an amount of acids [A](t=0) (see (Equation 1)) generated from PAG by exposure to a position (x,y,z) on a resist film can be approximated to as in (Equation 12) in a region given by C×E×I(x,y,z)<<1.
[A](t=0)≈C×Eᵢ×I(x,y,z) (Equation 12)

In the case where the approximation of (Equation 12) is applied to (Equation 11), and if an electric field intensity in the direction of thickness of the resist film is uniformly (I(x,y,z)=I(x,y)), the following (Equation 13) is derived.
[A]₀(x0,y0)≈h′∫∫C×Eᵢ×I(x, y)·F(r)dxdy−G (Equation 13)

As is apparent from (Equation 13), the acid concentration [A]₀ (x0,y0) on the resist film at the interested position (x0,y0) is in proportion to an amount of light absorption (Eᵢ×I(x,y)) in the resist film at the reference position (x,y) or an electric field intensity (I(x,y)) in the resist film at the reference position (x,y). Therefore, in order to calculate the thickness of the resist film at the interested position (x0,y0), as a representative value of the acid concentration [A]₀ (x0,y0), the amount of light absorption or the electric field intensity of the resist film at each reference position can be used.

As shown in (Equation 13), the acid concentration [A]₀(x0,y0) on the resist film at the interested position (x0,y0) is in proportion to an effective amount of light irradiation Eᵢ at the reference position (x,y). Therefore, in order to calculate the thickness of the resist film at the interested position (x0,y0), as a representative value of the acid concentration [A]₀(x0,y0), an amount of light irradiation onto the resist film at each reference position can be used. Constants h′ and G and a distribution function F(r) are determined by at least one of an experiment method and an analytic method.

The (Equation 13) has a form which is simpler than the equation described in the first and second embodiments. Therefore, a calculation time can be made shorter than that in the first or second embodiment.

However, since (Equation 13) includes a large number of approximations, calculation accuracy may be lower than that in the first or second embodiment. Therefore, in order to reduce the probability of erroneously determining a mask data to be determined as a critical pattern as a pattern which is not a critical pattern, the above predetermined threshold value is preferably shifted to a slightly large value (necessary resist film thickness is made slightly large).

### Fourth Embodiment

In this embodiment, mask data assumes a DRAM or the like including a periodical pattern portion such as a set of cell patterns having a high pattern density and a pattern portion such as a peripheral circuit pattern having a low pattern density.

In the case where an interested position is selected from the periodical pattern portion in the mask data, process conditions at interested positions are equal to each other. For this reason, a critical pattern can be easily decided.

More specifically, in the case where an interested position is selected from the periodical pattern portion, conditions (various parameters or the like) of simulation performed by the functional unit 4 (see FIG. 1) do not substantially change except for an acid concentration. Therefore, an acid concentration [A]₀_{_{—}}ₜₕ of the intermediate layer in which the resist film thickness is smaller than the threshold value is calculated in advance, and the acid concentration [A]₀(x0,y0) of the intermediate layer on the resist film corresponding to the interested position (x0,y0) is compared with the threshold value, so that it can be decided whether the interested position (x0,y0) is a critical pattern. More specifically, a critical pattern can be decided on the basis of the acid concentration [A]O(x0,y0) of the intermediate layer at an interested point without performing the simulation using (Equation 1) to (Equation 6) by the functional unit 4 (see FIG. 1).

As a matter of course, the acid concentration [A]₀(x0,y0) of the intermediate layer above the resist film corresponding to the interested position (x0,y0) changes depending on a scale of the periodical pattern portion, a distance from a boundary between the periodical pattern portion and the peripheral circuit portion to the interested position, and the like.

### Fifth Embodiment

In this embodiment, simulation based on a convenient model using a correlation between an effective amount of irradiation onto a resist film or an amount of modulation thereof and a dissolution rate of the resist film or a decrease in thickness of the resist film corresponding to the amount will be described below. The amount of modulation corresponds to an amount of distribution obtained by performing arbitrary z-transformation to an effective irradiation amount distribution typified by a convolution integral value of an effective amount of irradiation onto a resist film described in Japanese Patent 3297791 or a convolution integral value of an effective amount of irradiation onto a resist film by a value corresponding to two types of average diffusion lengths obtained by extending the above convolution integral value.

In this embodiment, formation of a table or a relational expression representing a relation between the effective amount of irradiation onto the resist film or the amount of modulation thereof and a dissolution rate of the resist film or the decrease in film thickness corresponding to the amount is important.

Prior to the description about this embodiment, open exposure (Open exposure) will be described.

The Open exposure means exposure performed through a mask having an opening pattern sufficiently larger than a distance in which optical proximity acts or exposure performed without any mask. However, depending on the mechanism of an exposure device, in the case where an exposure area is limited by a blind mechanism of the exposure device, diffracted light is generated at a blind end to irradiate exposure light onto an area except for the Open exposure area or to cause an error in the amount of exposure to the exposure area. In the case where the mask is not used, a flare is generated because no mask is present on an optical path. As a result, an error may be caused in an amount of exposure to the Open exposure area. For this reason, as the Open exposure, exposure performed through a mask having an opening which is formed in a sufficiently large region and the periphery of which is shielded by a shielding film from light is preferably used.

The same effect as that in the Open exposure can also be obtained by a gray-tone mask. The gray-tone mask mentioned here includes not only a structure in which a light transmission is changed by a material of a light-irradiated portion or a film thickness but also a structure in which only O-order diffracted light is irradiated by using a mask in which a pattern smaller than a resolution limit is arranged. In this case, a ratio of an amount of exposure of O-order diffracted light actually irradiated onto a wafer to an amount of exposure to the mask is calculated, and the amount of exposure to the mask is multiplied by the ratio, so that an amount of exposure onto the actual wafer must be calculated.

In general, an amount of exposure of light irradiated by an exposure device is input as a discrete data expressed by a predetermined significant figure. For this reason, in the case where a set value is small, relative data density of the amount of exposure light becomes low. In addition, in the case where an amount of exposure is very small, a filter for adjusting a transmittance in the exposure device may be used. However, an effective amount of exposure of the filtered light may be disadvantageously different from a set amount of exposure.

In contrast to this, in the case where the gray-tone mask is used, a necessary amount of exposure increases. For this reason, the problem of the significant figure in the input of the amount of exposure is moderated. The data density of the amount of exposure is increased to make it possible to improve the reliability of data.

The Open exposure has been described above.

The embodiment using the Open exposure will be described below in detail.

In the embodiment, a critical pattern is extracted on the basis of a relation between acids vapored from a resist film around an interested position and attached to the resist film at the interested position and a decrease in film thickness at the interested position.

For this purpose, an expression or a table representing a relation among an amount of exposure to the resist film at the interested position, an amount of acids attached to the resist film at the interested position, and a decrease in thickness of the resist film at the interested position is formed. Formation of the expression or the table includes six roughly classified stages.

In the first stages, an effective maximum distance Lₘₐₓ in which acids vapored from a certain resist film moves and attaches to the resist film is estimated.

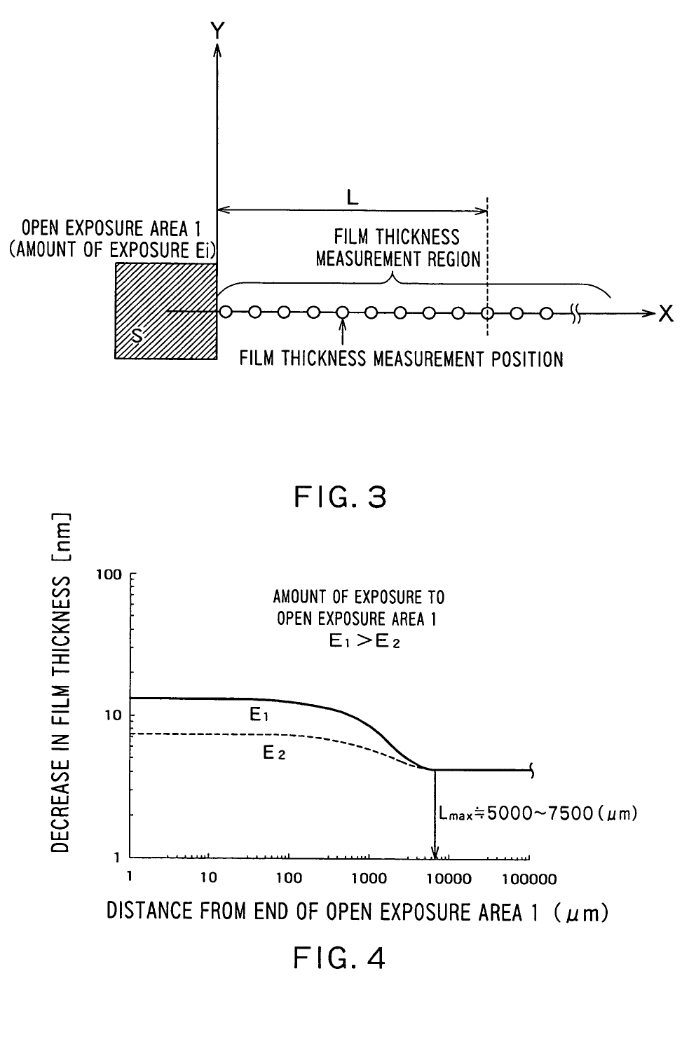

FIG. 3 is a graph showing a state in which the thickness of the resist film is measured at a plurality of positions.

More specifically, Open exposure is performed to Open exposure area 1 of the resist film at an amount of exposure Eᵢ, and PEB and development are performed. Thereafter, a distance L from an end of the Open exposure area 1 is changed to measure a resist film thickness. This measurement is performed while changing the amount of exposure Eᵢ. In order to improve the sensitivity of detection of a decrease in film thickness, the Open exposure is preferably performed at a high amount of exposure at which almost part of photo-acid generators is transferred into acids in the resist film. Even though the area size of the Open exposure is increased, the same effect as described above can be obtained.

FIG. 4 is a graph showing measurement results in FIG. 3.

In FIG. 4, relations between distances from an end of the Open exposure area 1 and decreases in thickness are shown with respect to the two amounts of exposure E₁ and E₂.

The maximum distance Lₘₐₓ to a position where vapored acids is attached is estimated by using FIG. 4. More specifically, a distance in which the decreases in thickness obtained at the amounts of exposure E₁ and E₂ stop differing from each other is estimated as the maximum distance Lₘₐₓ. In the case where the maximum distance Lₘₐₓ has been known already, the first stage may be omitted.

In the second stage, a correlation between the distance L from the center of the Open exposure area 1 and the decrease in film thickness is acquired within the range of the maximum distance Lₘₐₓ from an end of the Open exposure area 1.

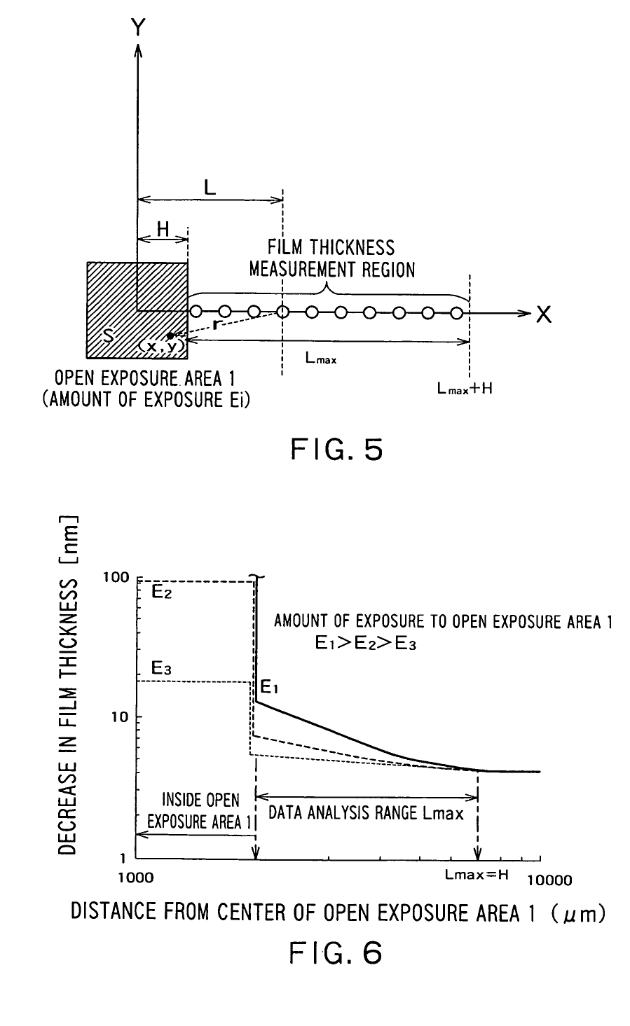

FIG. 5 is a graph showing a manner in which, after Open exposure is performed to the Open exposure area 1 at a certain amount of exposure Eᵢ, a correlation between the distance L from the center of the Open exposure area 1 in an x-axis direction and the decrease in film thickness is acquired. A measurement range extends from an end of the Open exposure area 1 by the maximum distance Lₘₐₓ in the x-axis direction, i.e., extends from the center of the Open exposure area 1 by H (distance from the center of the Open exposure area 1 to the end of the Open exposure area 1)+the maximum distance Lₘₐₓ in the x-axis direction.

In the above description, an origin of the distance L is defined as the center of the Open exposure area 1. However, the origin of the distance L is not limited to the center of the Open exposure area 1. In consideration of a substantial change of the size of the Open exposure area 1 due to diffusion of acids in the resist film, the center of the Open exposure area 1 is desirably defined as the origin.

In the case where a plurality of Open exposure areas are formed on the same wafer, i.e., when measurements are performed at a plurality of positions on the same wafer in the stage, the Open exposure areas are arranged with an interval of an unexposed region having a length which is twice or more the maximum distance Lₘₐₓ obtained in the first stage such that the Open exposure areas influent each other.

In order to improve the accuracy of experiment data, Open exposure is performed at the same amount of exposure Eᵢ at different positions on the same wafer or different wafers, an error caused by positions on the wafer such as temperature-increase characteristics of a PEB unit and a flowing direction of a developing solution is absorbed, so that measurements are desirably performed. The film thickness may be measured in not only the x-axis direction but also the y-axis direction.

In the third stage, the same operation as in the second stage is performed while changing the amount of exposure Eᵢ to the Open exposure area 1. In this manner, as shown in FIG. 6, a graph showing relations between distances L from the center of the Open exposure area 1 and the decreases in thickness are acquired with respect to the amounts of exposure Eᵢ (i=1, 2, . . . , n).

In this stage, the amounts of exposure Eᵢ are desirably changed within the range of an appropriate amount of exposure in settings input to the exposure device. The appropriate amount of exposure is a range of an amount of exposure in which the dimensions of a resist pattern to be formed are set in the range of desired dimensions, and is calculated in consideration of an error of mask processing, fluctuations in amount of exposure in exposure, and the like. In this stage, an amount of exposure at which a resist film having values such as a median of a range of desired dimensions and a mode value can be formed is calculated, and an amount of exposure which is approximately 1.2 times the amount of exposure at most is practically used as the appropriate amount of exposure.

In the fourth stage, experiment data (see FIG. 6), which have been obtained in the third stage, related to a function ΔTr(L, Ei, Dj=0) of a decrease in film thickness obtained by the amounts of exposure Eᵢ (i=1, 2, . . . , n) and the distance L from the center of the Open exposure area 1 is analyzed to calculate a relation between the decrease in film thickness and an amount of attached acids in a predetermined region (resist film in a range extending from the center of the Open exposure area 1 by the distance Lₘₐₓ+H). This will be described in more detail.

It is known that an acid concentration [A]₀ in a vapor above the resist film at the interested position and an amount of acids A_{add} attached to the resist film at the interested position strongly correlate to each other. In simulation, the relation has almost linearity. Under the conditions of the Open exposure, the electric field intensity (I(x,y)) can be approximated to a constant. For this reason, the electric field intensity (I(x,y)) and a PhotoSpeed C can be expressed as one constant H. Under the above conditions, the following (Equation 14) can be derived from (Equation 11).

$${A}_{add} ( x0 , y0 ) \approx {HE}_{i} \int {\int }_{s} F ( r ) ⅆ x ⅆ y - {G}^{′} \qquad ( Equation 14 )$$

where H and G′ are constants, and F(r) is a distribute function representing a rate of attachment of acids vapored at a position in the Open exposure area 1 to a position keeping a distance r (see FIG. 5 and Equation 15) away from the position in the Open exposure area 1.
   r=\sqrt{L²+y²} (Equation 15)

In (Equation 14), an integral region S is an entire region of the Open exposure area 1.

In the case where a function ΔTr(L, Eᵢ,Dj=0) of a decrease in film thickness by the amount of exposure Eᵢ to the Open exposure area 1 and the distance L from the same area which are measured in the second and third stages is transformed into a function T (Dj=0, A_{add}) of the decrease in film thickness by amount of attached acids A_{add}, the function can be described in the form of (Equation 16) as a general formula.

$$Δ Tr ( L , {E}_{i} , {D}_{j} = 0 ) = T ( {D}_{j} = 0 , {HE}_{i} \int {\int }_{s} F ( r ) ⅆ x ⅆ y - {G}^{′} ) \qquad ( Equation 16 )$$

In this (Equation 16), in the case where the distribution function F(r) and the constants H and G′ are determined, if the amount of attached acids A_{add} is the same, it is assumed that the decrease in film thickness is the same. Actually, a function system of F(r) is assumed, and the constants H and G′ are calculated.

When the (Equation 16) is derived, as in case of (Equation 13), approximations are performed such that the equation has a simple form. However, as in case of (Equation 10) or (Equation 11), the degree of approximations may be further reduced.

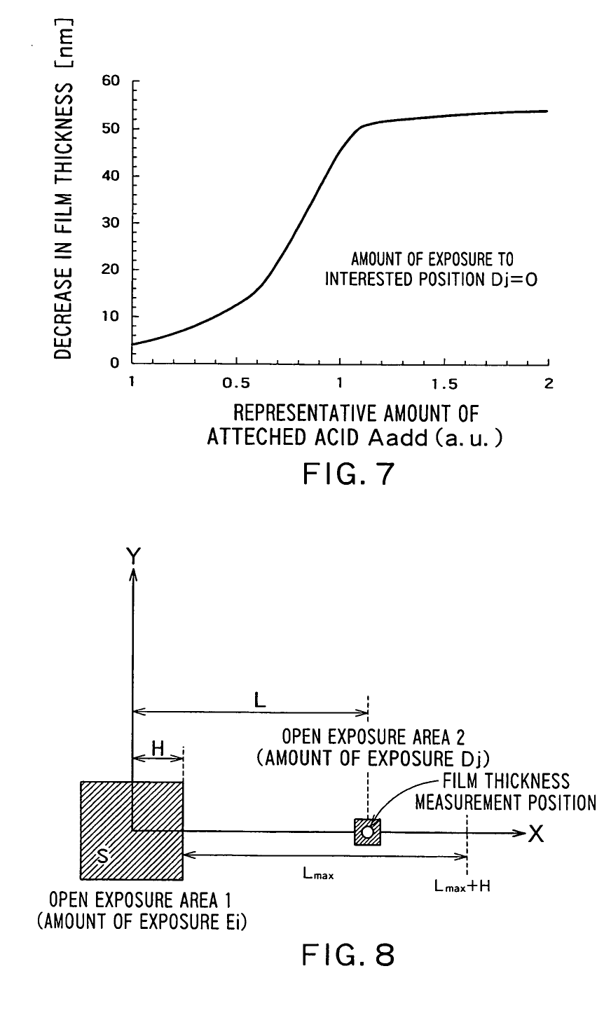

With the above operation, a relation between an amount of attached acids in an unexposed portion and a decrease in film thickness is obtained as shown in FIG. 7.

The procedure advances to the fifth step. FIG. 8 is a graph for explaining the fifth stage. In the fifth stage, Open exposure is performed to the Open exposure area 1 at an amount of exposure Eᵢ, Open exposure is performed to an Open exposure area 2 keeping a distance L away from the center of the Open exposure area 1 at an amount of exposure Dⱼ, and PEB and development are performed. Thereafter, the thickness of the resist film in the Open exposure area 2 is measured. In this case, the distance L is a distance between the center of the Open exposure area 1 and the center of the Open exposure area 2.

An amount of attached acids to the Open exposure area 2 can be changed by the amount of exposure Dⱼ to the Open exposure area 2, the Open exposure area 2 is made to narrow as much as possible within an allowable limit of a thickness measurer.

In the case where the size of the Open exposure area 2 is sufficiently small, i.e., in the case where attachment of acids vapored from the Open exposure area 2 itself to a measurement position can be neglected, the analysis result obtained in the fourth stage can be used as an amount of acids attached to a film thickness measurement position in the Open exposure area 2. In this manner, a decrease in film thickness T(D1,A_{add}1) in the case where the amount of attached acids and an amount of exposure to the film thickness measurement position are represented by A_{add}1 and D₁, respectively can be calculated.

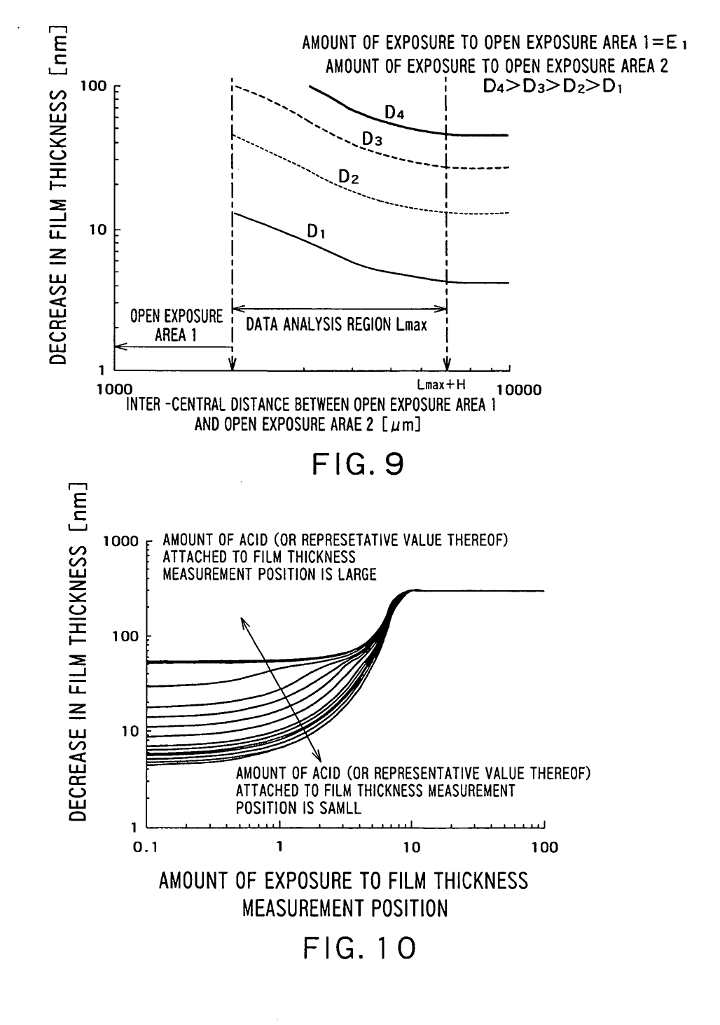

In the next sixth stage, the same operations as in the fifth embodiment are performed while changing the amount of exposure Dⱼ to the Open exposure area 2 and the inter-central distance L between the Open exposure areas 1 and 2. In this manner, in the case where an amount of exposure to the Open exposure area 1 is a specific amount of exposure, correlative data between the distance L and the decrease in film thickness with respect to the amounts of exposure Dⱼ can be obtained. An example of the correlative data is shown in FIG. 9.

In addition, at least one of the distance L and the amount of exposure Eᵢ is controlled to change the amount of acids A_{add} attached to a measurement position. In this manner, as shown in FIG. 10, a decrease in film thickness T (Dⱼ, A_{add}) in the case where an amount of exposure Dⱼ to the film thickness measurement position and the amount of acids A_{add} attached to the film thickness measurement position are set is obtained. More specifically, an expression representing a relation among the amount of exposure to the film thickness measurement position, the amount of acids attached to the film thickness measurement position, and the decrease in film thickness at the film thickness measurement position can be obtained.

Extraction of a critical pattern using the expression of the decrease in film thickness obtained by the procedure of the first to sixth stages will be described below.

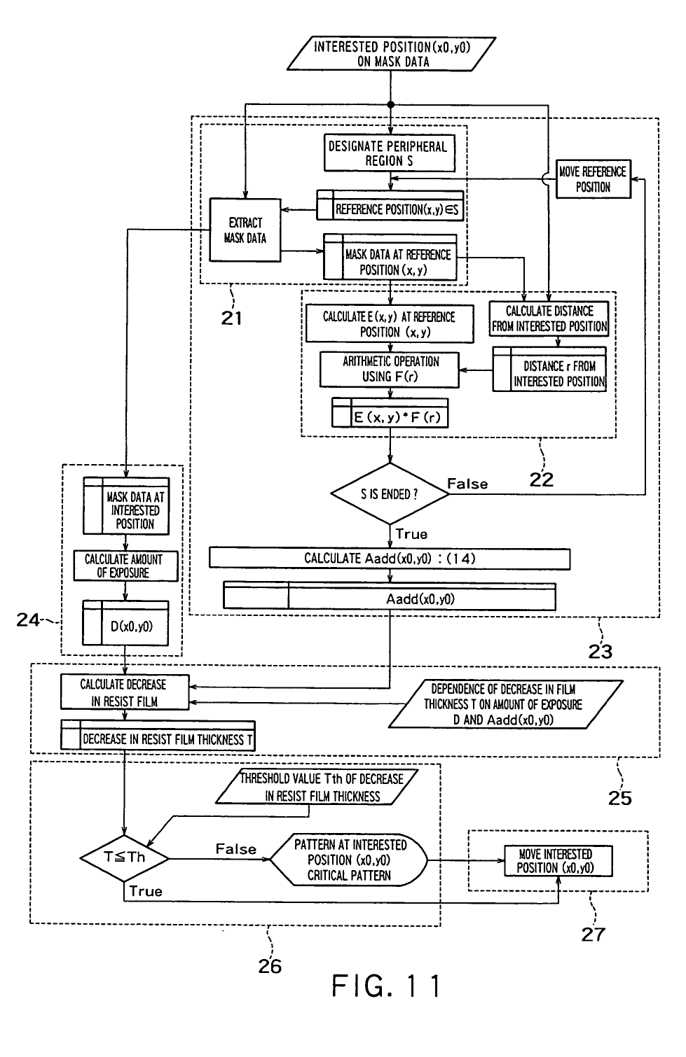

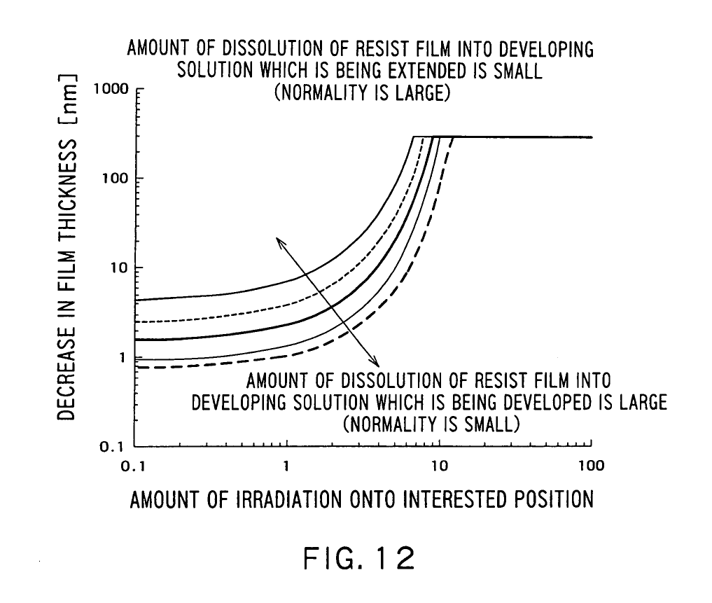

FIG. 11 is a block diagram showing the configuration of a critical pattern extracting system for realizing extraction of the critical pattern.

The critical pattern extracting system includes a first functional unit 21 to a seventh functional unit 27.

The first functional unit 21 extracts mask data at an interested position (x0,y0) from mask data acquired by a known method. The first functional unit 21 designates the inside (peripheral region S) of a circle centered on the interested position (x0,y0) and having a radius Lₘₐₓ. The first functional unit 21 specifies a reference position (x,y) included in the peripheral region S and extracts mask data at the specified reference position (x,y).

The second functional unit 22 calculates an effective amount of exposure E(x,y) to a resist film corresponding to the reference position (x,y). At this time, a coordinate system may be transformed from a coordinate system on the mask data into a coordinate system on a wafer. In place of E(x,y), a predetermined arithmetic operation result, e.g., a result obtained by performing convolution integral using a predetermined average diffusion length to E(x,y) may be used. The second functional unit 22 calculates a distance r between the interested position (x0,y0) and the reference position (x,y) on the resist film to perform a predetermined arithmetic operation (E(x,y)*F(r)) using the distribution function F(r).

In the case where the third functional unit 23 performs the predetermined arithmetic operation (E(x,y)*F(r)) with respect to all the reference positions (x,y) in the peripheral region S, the third functional unit 23 applies (Equation 14) to calculate an amount of acids A_{add}(x0,y0) attached to the resist film corresponding to the interested position (x0,y0). The integral region of (Equation 14) is the peripheral region S.

The fourth functional unit 24 uses the mask data at the interested position (x0,y0) to calculate an effective amount of exposure D(X0,y0) to the resist film corresponding to the interested position (x0,y0). At this time, the coordinate system may be transformed from a coordinate system on the mask data into the coordinate system on a wafer. As the effective amount of exposure D(x0,y0) to the resist film corresponding to the interested position (x0,y0), an arithmetic operation result obtained by the second functional unit 22, i.e., the amount of exposure E(x,y) to the resist film corresponding to the reference position (x,y) may be used.

The fifth functional unit 25 applies the effective amount of exposure D(x0,y0) to the resist film corresponding to the interested position (x0,y0) and the amount of acids A_{add}(x0,y0) attached to the resist film corresponding to the interested position (x0,y0) to the relational expression or the table of the decreases in thickness calculated in advance as described above to calculate the decrease in film thickness T(D(x0,y0), A_{add}(x0,y0)) in the resist film corresponding to the interested position (x0,y0).

The sixth functional unit 26 compares the decrease in film thickness T(D(x0,y0), A_{add}(x0,y0)) with a threshold value Tₜₕ of the decrease in film thickness of the resist film thickness. In the case where the decrease in film thickness T(D(x0,y0), A_{add}(x0,y0)) is larger than the threshold value Tₜₕ, the sixth functional unit 26 determines the interested position (x0,y0) as a critical pattern. At this time, pattern dimensions may also be added to the criteria.

The seventh functional unit 27 performs the processes of the first functional unit 21 to the sixth functional unit 26 again while moving the interested position.

In the above processes, for example, when an effective amount of exposure to a wafer is calculated, an intermediate calculation result is stored. The intermediate calculation result may be repeatedly used to omit the same calculation, so that a calculation time can be desirably shortened.

As described above, according to the embodiment, an amount of acids attached to a resist film corresponding to an interested position on mask data and an amount of exposure to the resist film are applied to a relational expression or a table of decreases in film thickness which is formed in advance to make it possible to easily calculate a decrease in film thickness of the resist film corresponding to the interested position. More specifically, a judge for a critical pattern can be performed easier in the fifth embodiment than in the first embodiment.

### Sixth Embodiment

The embodiment will describe the following case. That is, a process generation amount is an amount of dissolution of a resist film under a developing path of a developing solution in the initial stage of a developing step, and a process affecter amount is a variation in normality of the developing solution due to dissolution of the resist film (or an amount of dissolution of the resist film into a developing solution to be extended to the interested position).

In general, in a lithography step, the normality of a developing solution is decreased by the resist film which is dissolved until the developing solution is reached to an interested position. In this manner, the shape (dimensions and thickness) of the resist film at the interested position is different from an original shape disadvantageously. Mainly, this resist film causes a problem in a KrF resist.

As a concrete phenomenon, in the case where a large-scale dissolved portion of the resist film is present on the upstream side of the developing solution to be extended, the resist dimensions of the resist film on the downstream side disadvantageously become big, or the resist film disadvantageously has a T-top shape.

Therefore, in the embodiment, a critical pattern is extracted in consideration of a decrease in normality of the developing solution due to dissolution of the resist film.

A variation in normality of the developing solution with respect to an amount of dissolution of the resist film is acquired in advance. Dependence of a dissolution rate (see (Equation 6)) on a standardized protection rate is acquired while changing the normality. More specifically, the normality of the developing solution is made constant, and a relation between the dissolution rate and the standardized protection rate is acquired. This operation is performed while changing the normality. On the basis of these results, dependences of the dissolution rate on the amount of resist dissolution and the standardized protection rate are determined. More specifically, a function for calculating the dissolution rate is determined on the basis of the amount of resist dissolution and the standardized protection rate, and the function is transferred into a format which can be used in the following simulation.

A critical pattern extracting procedure according to the embodiment is applied to a commercial resist process simulator which is made in consideration of a reaction elementary step in PEB, to extract a critical pattern. The procedure will be described below with reference to a flow chart shown in FIG. 15.

As a first stage, a first functional unit 31 extracts mask data at a interested position (x0,y0) from mask data formed by a known method in advance. The first functional unit 31 determines a predetermined peripheral region S centered on the interested position (x0,y0), specifies a reference position (x,y) included in the peripheral region S, and extracts mask data at the reference position (x,y).

In a second stage, a second functional unit 32 calculates a distance between the interested position and the reference position. On the other hand, on the basis of a distance between the reference position and an opening of a developing solution nozzle, a extending rate of a developing solution, and an average extending direction of the developing solution, an amount of dissolution of a resist film at the reference position into the developing solution passing through the reference position is calculated. The amount of dissolution and the distance between the interested position and the reference position is used to perform a first arithmetic operation. The first arithmetic operation is performed to all the reference positions in the peripheral region S.

Specifying of the peripheral region S described in the first and second stages will be described in more detail. The shape of the peripheral region S is the shape of a region in which a developing solution is extended from the developing solution nozzle to the interested position.

Actually, the shape of the peripheral region S is a complex shape depending on a extending rate of the developing solution, a moving direction of the nozzle (depending on the type of the nozzle), a rotating direction of a wafer, an arrangement of the opening of the nozzle, and the like. In addition, since the wafer also rotates except for some slit developing, the extending direction of the developing solution with respect to the interested position changes depending on the position of the wafer of an exposure shot.

It is very difficult to strictly consider the above problem. The problems can be approximately processed by the following means.
(1) On the basis of an average distance between an interested position and a developing solution nozzle and an average flow rate of a developing solution on a wafer, the shape of the peripheral region S to be considered is determined.
(2) Positive and negative directions of each of two axes perpendicular to each other at the interested position serving as an origin are set for the peripheral region S. Different directions may also be considered.
(3) With respect to the plurality of peripheral regions with respect to the interested position, the processes in the first and second stages and the following third stage are performed, and a maximum process affecter amount or a second arithmetic operation value is employed.
(4) By using the maximum process affecter amount, the processes in the following fourth and fifth stages are performed to decides where the interested position is a critical pattern or not.

As the third stage, a third functional unit 33 uses the first arithmetic operation result to calculate, as a process affecter amount at the interested position, an amount of resist dissolved into a developing solution extended to the interested point or a normality of the developing solution.

As the fourth stage, a fourth functional unit 34 calculates developing parameters for the interested point on the basis of a table or a relational expression of developing parameters depending on the amount of resist dissolution or normalities serving as the process affecter amount. In addition, the thickness of the resist film at the interested point is simulated by also using parameters (reaction coefficient, diffusion constant, or the like) which do not depend on the process affecter.

As the fifth stage, a fifth functional unit 35 decides whether the thickness of the resist film at the interested position is a predetermined threshold value or more. More specifically, the fifth functional unit 35 decides whether the dissolution rate of the resist film at the interested position is the threshold value or more. In the case where the dissolution rate is the predetermined threshold value or more, mask data corresponding to the interested position is not determined as a critical pattern. In the case where the dissolution rate is smaller than the predetermined threshold value, the mask data is determined as a critical pattern.

As a sixth stage, a sixth functional unit 36 moves the interested position to determine about other interested positions.

As described above, according to the embodiment, a critical pattern is extracted in consideration of a variation in dissolution rate of the resist film caused by a decrease in normality of the developing solution by dissolution of the resist film. For this reason, the critical pattern can be extracted in consideration of the thickness of the resist film.

In a conventional technique, since a critical pattern is extracted in consideration of only dimensions in in-plane directions of the resist film, a pattern which is not a critical pattern is probably extracted as a critical pattern. In contrast to this, in the embodiment, a critical pattern is extracted in consideration of a variation in dissolution rate, i.e., directions of thickness of the resist film. For this reason, the probability of extracting a normal pattern as a critical pattern can be considerably reduced.

### Seventh Embodiment

This embodiment is obtained by simplifying a simulate model in the sixth embodiment.

Only changed points will be described below.

In place of acquisition of developing parameters depending on a process affecter amount, a correlation between an effective amount of irradiation (or modulation thereof) onto a resist film depending on the process affecter amount and a decrease in film thickness of the resist film (or a dissolution rate) is acquired.

First to third stages are the same as the first to third stages described above.

In a fourth stage, a correlation between an effective amount of irradiation at the interested position and the decrease in film thickness is calculated on the basis of a correlation between an effective amount of irradiation having dependence on a normality (or an amount of dissolution of a developing solution) serving as the process affecter amount and the decrease in film thickness and the process affecter amount at the interested position. The decrease in film thickness at the interested position is calculated on the basis of the correlation and the effective amount of irradiation at the interested position.

In a fifth stage, a decision is made by comparing the calculated value of the resist film thickness calculated in the fourth stage with a threshold value.

According to the embodiment, the simulation model in the seventh embodiment is simpler than that in the sixth embodiment. For this reason, a calculation time can be advantageously shortened.

### Eighth Embodiment

Functions realized by the critical pattern extracting systems described in the first to seventh embodiments, i.e., the functions for executing the critical pattern extracting procedures described in the first to seventh embodiments can also be realized by causing a computer to execute a program created by using a usual programming technique. This program may be stored in a predetermined recording medium.

### Ninth Embodiment

After a critical pattern is extracted on the basis of the critical pattern extracting procedures described in the first to seventh embodiments, mask data is corrected by using the information of the critical pattern. A photomask manufactured on the basis of the corrected mask data is prepared, a pattern formed in the photomask is transferred onto a resist film on a wafer by exposure. In this manner, exposure is performed by using the photomask manufactured on the basis of the corrected mask data to make it possible to manufacture a semiconductor device having desired performance.

1. A critical pattern extracting method which extracts critical patterns from mask data for manufacturing a photomask used in a lithography step, comprising at least:
extracting mask data of a peripheral region within a predetermined range from an interested portion to be decided in the mask data;
defining portions constituting the peripheral region as reference portions and calculating process generation amounts generated from the each reference portion in the lithography step by simulation;
performing a predetermined arithmetic operation by using the process generation amounts and distances between the interested portion and the each reference portion;
performing multiple integral of an arithmetic operation value obtained by the predetermined arithmetic operation in the peripheral region or an arithmetic operation equivalent to the multiple integral to calculate a process affecter amount; and
comparing the process affecter amount with a predetermined threshold value.

2. A critical pattern extracting method which extracts a critical pattern from mask data for manufacturing a photomask used in a lithography step, comprising at least:
extracting mask data of a peripheral region within a predetermined range from an interested portion to be decided in the mask data;
defining portions constituting the peripheral region as reference portions and calculating process generation amounts generated from the each reference portion in the lithography step by simulation;
performing a predetermined arithmetic operation by using the process generation amounts and distances between the interested portion and the each reference portion;
performing multiple integral of an arithmetic operation value obtained by the predetermined arithmetic operation in the peripheral region or an arithmetic operation equivalent to the multiple integral to calculate a process affecter amount;
performing a further predetermined arithmetic operation by using the mask data of the interested portion, the process affecter amount, and a simulation parameter changing depending on the process affecter amount; and
comparing an arithmetic operation value calculated by the further predetermined arithmetic operation with a predetermined threshold value.

3. The critical pattern extracting method according to claim 2, wherein the arithmetic operation value calculated by the further predetermined arithmetic operation is a thickness of a resist film corresponding to the interested portion.

4. The critical pattern extracting method according to claim 2 wherein, in extraction of the mask data at the peripheral region and calculation of the distance from the interested portion to the each reference portion, processing is performed such that a boundary of effective mask data region in which a pattern is actually formed on a wafer is considered as being continued to a boundary of the mask data region opposing the boundary.

5. The critical pattern extracting method according to claim 2, wherein the process generation amount is an amount of acids vapored from a resist film in at least one of an exposure step and a PEB step or a representative value thereof.

6. The critical pattern extracting method according to claim 5, wherein the representative value of the amount of vapored acids is an effective amount of irradiation onto the resist film corresponding to the reference portion.

7. The critical pattern extracting method according to claim 5, wherein the representative value of the amount of vapored acids is one of an electric intensity and an amount of light absorption of the resist film corresponding to the reference portion.

8. The critical pattern extracting method according to claim 5, wherein the representative value of the amount of vapored acids is an amount of acids generated at the resist film corresponding to the reference portion.

9. The critical pattern extracting method according to claim 5, wherein the representative value of the amount of vapored acids is a difference between a amount of acids generated at the resist film and an amount of base substance in the resist film.

10. The critical pattern extracting method according to claim 1, wherein the process generation amount is an amount of acids vapored from a resist film in at least one of an exposure step and a PEB step or a representative value thereof.

11. The critical pattern extracting method according to claim 10, wherein the representative value of the amount of vapored acids is an effective amount of irradiation onto the resist film corresponding to the reference portion.

12. The critical pattern extracting method according to claim 10, wherein the representative value of the amount of vapored acids is one of an electric intensity and an amount of light absorption of the resist film corresponding to the reference portion.

13. The critical pattern extracting method according to claim 10, wherein the representative value of the amount of vapored acids is an amount of acids generated at the resist film corresponding to the reference portion.

14. The critical pattern extracting method according to claim 10, wherein the representative value of the amount of vapored acids is a difference between a amount of acids generated at the resist film and an amount of base substance in the resist film.

15. The critical pattern extracting method according to claim 1, wherein the process generation amount is an amount of resist film dissolved in a developing solution within a predetermined period of time in a developing step.

16. The critical pattern extracting method according to claim 2, wherein the process generation amount is an amount of resist film dissolved in a developing solution within a predetermined period of time in a developing step.

17. A critical pattern extracting program of making a computer execute a critical pattern extracting method which extracts a critical pattern from mask data for manufacturing a photomask used in a lithography step, comprising at least:
extracting mask data of a peripheral region within a predetermined range from an interested portion to be decided in the mask data;
defining portions constituting the peripheral region as reference portions and calculating process generation amounts generated from the each reference portion in the lithography step by simulation;
performing a predetermined arithmetic operation by using the process generation amounts and distances between the interested portion and the each reference portion;
performing multiple integral of an arithmetic operation value obtained by the predetermined arithmetic operation in the peripheral region or an arithmetic operation equivalent to the multiple integral to calculate a process affecter amount; and
comparing the process affecter amount with a predetermined threshold value.

18. A critical pattern extracting program of making a computer execute a critical pattern extracting method which extracts a critical pattern from mask data for manufacturing a photomask used in a lithography step, comprising at least:
extracting mask data of a peripheral region within a predetermined range from an interested portion to be decided in the mask data;
defining portions constituting the peripheral region as reference portions and calculating process generation amounts generated from the each reference portion in the lithography step by simulation;
performing a predetermined arithmetic operation by using the process generation amounts and distances between the interested portion and the each reference portion;
performing multiple integral of an arithmetic operation value obtained by the predetermined arithmetic operation in the peripheral region or an arithmetic operation equivalent to the multiple integral to calculate a process affecter amount;
performing a further predetermined arithmetic operation by using the mask data of the interested portion, the process affecter amount, and a simulation parameter changing depending on the process affecter amount; and
comparing an arithmetic operation value calculated by the further predetermined arithmetic operation with a predetermined threshold value.

19. A method of manufacturing a semiconductor device, comprising:
extracting mask data of a peripheral region within a predetermined range from an interested portion to be decided in mask data for manufacturing a photomask used in a lithography step;
defining portions constituting the peripheral region as reference portions and calculating process generation amounts generated from the each reference portion in the lithography step by simulation;
performing a predetermined arithmetic operation by using the process generation amounts and distances between the interested portion and the each reference portion;
performing multiple integral of an arithmetic operation value obtained by the predetermined arithmetic operation in the peripheral region or an arithmetic operation equivalent to the multiple integral to calculate a process affecter amount;
comparing the process affecter amount with a predetermined threshold value;
extracting a critical pattern from the mask data for manufacturing the photo mask based on a result of the comparing; and
preparing a photomask manufactured on the base of mask data which is corrected by using a information of a extracted critical pattern and exposuring a resist film on a wafer by using the photomask.

20. A method of manufacturing a semiconductor device, comprising:
extracting mask data of a peripheral region within a predetermined range from an interested portion to be decided in the mask data;
defining portions constituting the peripheral region as reference portions and calculating process generation amounts generated from the each reference portion in the lithography step by simulation;
performing a predetermined arithmetic operation by using the process generation amounts and distances between the interested portion and the each reference portion;
performing multiple integral of an arithmetic operation value obtained by the predetermined arithmetic operation in the peripheral region or an arithmetic operation equivalent to the multiple integral to calculate a process affecter amount;
performing a further predetermined arithmetic operation by using the mask data of the interested portion, the process affecter amount, and a simulation parameter changing depending on the process affecter amount;
comparing an arithmetic operation value calculated by the further predetermined arithmetic operation with a predetermined threshold value;
extracting a critical pattern from the mask data for manufacturing the photo mask based on a result of the comparing; and
preparing a photomask manufactured on the base of mask data which is corrected by using a information of a extracted critical pattern and exposuring a resist film on a wafer by using the photomask.
